(19) United States
(12) Patent Application Publication
(10) Pub. No.: US 2023/0335423 A1
(43) Pub. Date: Oct. 19, 2023

(54) MULTI-CHAMBER SEMICONDUCTOR PROCESSING SYSTEM WITH TRANSFER ROBOT TEMPERATURE ADJUSTMENT

(71) Applicant: Taiwan Semiconductor Manufacturing Company, Ltd., Hsinchu (TW)

(72) Inventors: Chia-Hsi Wang, Changhua County (TW); Yen-Yu Chen, Taichung City (TW)

(21) Appl. No.: 17/723,372

(22) Filed: Apr. 18, 2022

(51) Int. Cl. H01L 21/677; H01L 21/67; C23C 16/54; C23C 16/46; C23C 14/56

(52) U.S. Cl. CPC H01L 21/67742; H01L 21/67248; C23C 16/54; C23C 16/463; C23C 14/568; H01L 21/68707

(57) ABSTRACT

A multi-chamber semiconductor processing system is provided. The multi-chamber semiconductor processing system includes: a plurality of chambers, each of the plurality of chambers corresponding to a semiconductor process; a transfer chamber; a transfer robot in the transfer chamber and having a holding member capable of holding a wafer, the transfer robot configured to transfer the wafer among the plurality of chambers; a first temperature sensor mounted on the holding member and configured to detect a transfer robot temperature; and a temperature adjustment unit mounted on the transfer robot and configured to adjust the transfer robot temperature.

### FIELD

Embodiments of the present disclosure relate generally to semiconductor processing, and more particularly to multi-chamber semiconductor processing systems with transfer robot temperature adjustment.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various dielectric, semiconductor, and metal layers. The areas of the layer that are to be deposited or removed are controlled through photolithography. Each deposition and removal process is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating an example multi-chamber semiconductor processing system in accordance with some embodiments.

FIG. 2 is a block diagram illustrating an example control system in accordance with some embodiments.

FIG. 3 is a diagram illustrating is a schematic diagram illustrating an example PVD system in accordance with some embodiments.

FIG. 4A is a schematic diagram illustrating an example transfer robot in accordance with some embodiments.

FIG. 4B is a schematic diagram illustrating an example temperature adjustment unit in accordance with some embodiments.

FIG. 5 is a timing diagram illustrating the operation of the multi-chamber semiconductor processing system in accordance with some embodiments.

FIG. 6A is a diagram illustrating an example film formed under the target temperature in accordance with some embodiments.

FIG. 6B is a diagram illustrating an example film formed under a deviated temperature in accordance with some embodiments.

FIG. 7 is a flowchart diagram illustrating an example method in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

A multi-chamber semiconductor processing system is commonly used for semiconductor processing, which includes multiple processes such as physical vapor deposition (PVD), atomic layer deposition (ALD), and various kinds of chemical vapor deposition (CVD) (e.g., metal-organic chemical vapor deposition (MOCVD), atmospheric-pressure CVD (APCVD), low-pressure CVD (LPCVD), ultra-high-vacuum CVD (UHVCVD)). Each process corresponds to a chamber in the multi-chamber semiconductor processing system, and each chamber may have a different target temperature. If the actual temperature deviates from the target temperature, the grain size of the film formed may deviate from the target grain size. In addition, the properties of the film formed may be degraded.

Transfer robots are typically used in a multi-chamber semiconductor processing system to transfer the wafer from one chamber to another according to the process log. In some examples, one transfer robot is used. In other examples, two or more transfer robots are used. When the wafer is transferred by the transfer robot from a first chamber (having a first target temperature) to a second chamber (having a second target temperature higher than the first target temperature), the process to be conducted in the second chamber cannot begin until the temperature of the wafer ramps up precisely to the second target temperature. As a result, there is some delay time due to the temperature difference in different chambers. The delay time that may exist every time the wafer is transferred to a new chamber can collectively result in a loss in productivity of the multi-chamber semiconductor processing system. The loss in productivity becomes a more significant issue in situations like a global semiconductor shortage.

On the other hand, if the process to be conducted in the second chamber starts prematurely (i.e., before the temperature of the wafer reaches the second target temperature), the grain size of the film formed may deviate, and the properties of the film formed may be degraded, as explained above.

In accordance with some aspects of the disclosure, a multi-chamber semiconductor processing system and the operation thereof are provided. The multi-chamber semiconductor processing system includes multiple chambers, a transfer robot located in a transfer chamber, a temperature sensor mounted on the transfer robot, and a temperature adjustment unit mounted on the transfer robot. The transfer robot is configured to transfer the wafer among the chambers. The temperature sensor is configured to detect a transfer robot temperature. The temperature adjustment unit is configured to adjust the transfer robot temperature.

The temperature adjustment unit begins to adjust the transfer robot temperature 292 when the wafer is still going through a process in a first chamber, and the target temperature is the target temperature of a second chamber. When the wafer exits the first chamber, the temperature of the wafer begins to change (i.e., increase or decrease) as the transfer robot temperature changes toward the target temperature of the second chamber due to thermal conduction (because the wafer is placed on and in contact with the transfer robot). Therefore, by the time the transfer robot transfers the wafer to the second chamber, the transfer robot temperature and, therefore, the temperature of the wafer has reached the target temperature of the second chamber. Accordingly, the delay time due to the temperature difference in different chambers can be significantly reduced or completely avoided, thereby enhancing the productivity of the multi-chamber semiconductor processing system.

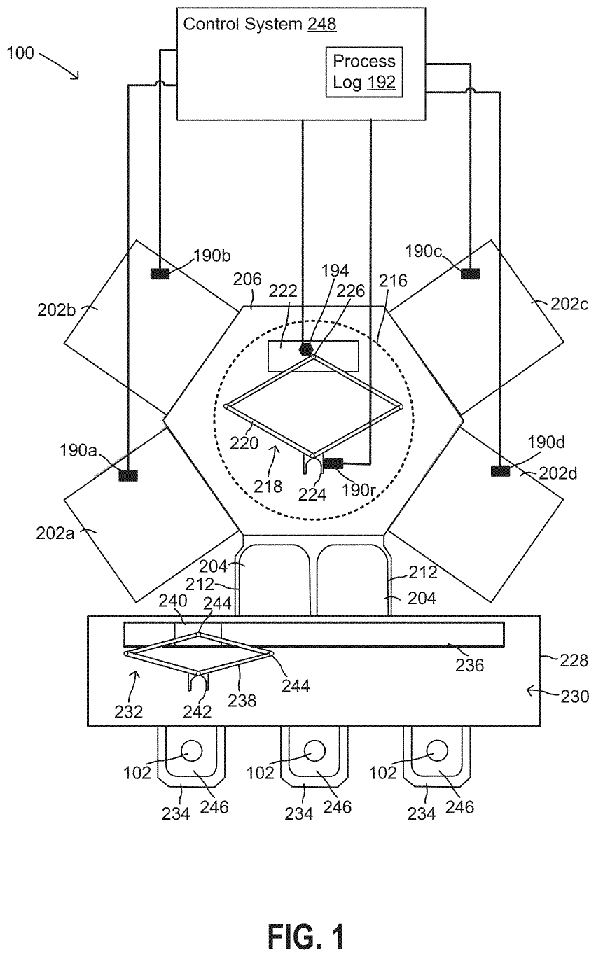

FIG. 1 is a schematic diagram illustrating an example multi-chamber semiconductor processing system 100 in accordance with some embodiments. The multi-chamber semiconductor processing system 100 is configured to process a wafer 102 or a batch of wafers 102 according to a process log 192 stored in, for example, a control system 248. In one example, a batch of wafers 102 are processed together, and the batch can include one hundred or more wafers 102. In another example, the multi-chamber semiconductor processing system 100 is configured to process a single wafer 102.

The multi-chamber semiconductor processing system 100 includes, among other things, a main frame 206, one or more load locks 204, multiple chambers 202a, 202b, 202c, and 202d (collectively, 202), wafer container loaders 234, wafer containers 246, a loading house 228, a control system 248. The main frame 206 is located at the center, and the one or more load locks 204 and the multiple chambers 202 are laterally spaced around and abutting the main frame 206. It should be understood that although two load locks 204 and four chambers 202 are illustrated in FIG. 1, this is not intended to be limiting. In other examples, other numbers (e.g., one, three, etc.) of load locks and other numbers (e.g., five, six, eight, ten, etc.) of chambers may be employed.

The wafer container loaders 234 are configured to support wafer containers (sometimes referred to as “pods”) 246. The wafer containers 246 can each accommodate a batch of wafers 102. In one embodiment, the wafer containers 246 are standard mechanical interface (SMIF) pods. In another embodiment, the wafer containers are front opening unified pods (FOUPs). Wafer containers 246 and the wafers 102 therein can be transported among various semiconductor processing systems.

The loading housing 228 is located between the wafer container loaders 234 and the load locks 204. In the example shown in FIG. 1, the loading housing 228 abuts the load locks 204 at one side, and the wafer container loaders 234 are arranged on an opposite side of the loading housing 228 as the load locks 204.

The loading housing 228 defines a loading area 230 accommodating a loading robot 232 configured to transfer wafers 102 between the wafer container loaders 234 and the load locks 204. In the example shown in FIG. 1, the loading robot 232 is arranged on a track 236 to move within the loading area 230. The loading robot 232 includes, in the example shown in FIG. 1, one or more rods 238 connected end to end between a motor 240 and a holding member 242 by one or more bearings 244. The motor 240 is configured to vertically, horizontally, and/or rotationally move the holding member 242 along the bearings 244. In one embodiment, the holding member 242 includes one or more blades, and each of the one or more blades includes a pair of laterally spaced fingers typically configured to support a single wafer 102. In one example, the holding member 242 includes five blades. In another embodiment, the holding member 242 includes one or more holding plates. It should be understood that the above embodiments or examples are not intended to be limiting, and the loading robot 232 may have various forms and designs.

Each of the load locks 204 are arranged in a load lock housing 212, abutting and mounted to a facet of the main frame 206. Each of the load locks 204 includes a corresponding load lock chamber configured to pass wafers 102 between environments on opposing sides of the load locks 204, while maintaining isolation between the environments. In some embodiments, the load lock chambers are individually sized to accommodate the same number of substrates as the chambers 202a-202d.

The main frame 206 includes a transfer chamber 216 central to the chambers 202a-202d and the load locks 204. The transfer chamber 216 accommodates a transfer robot 218 configured to transfer the wafer 102 among the chambers 202a-202d and the load locks 204, so as to facilitate loading and unloading of the wafer 102. During loading of the wafer 102, the wafer 102 is transferred from the load locks 204 to one or more of the chambers 202a-202d in a predetermined order according to the process log 192. Further, during unloading of the wafer 102, the wafer 102 is transferred from one of the chambers 202a-202d to the load locks 204. Although not shown in FIG. 1, the main frame 206 has openings that are aligned with corresponding sleeve doors located at the chambers 202a-202d and the load locks 204 to allow the transfer robot 218 to access the chambers 202a-202d during loading and unloading of the wafer 102. When loading and unloading are complete, the corresponding sleeve door closes and seals the corresponding opening. It should be understood that although the transfer of one wafer 102 is described above as an example, the transfer robot 218 is capable of transferring a batch of wafers 102 in other embodiments.

In the example shown in FIG. 1, the transfer robot 218 includes one or more rods 220 connected end to end between a motor 222 and a holding member 224 by one or more bearings 226. The motor 222 is configured to vertically, horizontally, and/or rotationally move the holding member 224 along the bearings 226. In one embodiment, the holding member 224 includes one or more blades, and each of the one or more blades includes a pair of laterally spaced fingers typically configured to support a single wafer 102. In one example, the holding member 224 includes five blades. In another embodiment, the holding member 224 includes one or more holding plates. It should be understood that the above embodiments or examples are not intended to be limiting, and the transfer robot 218 may have various forms and designs. It should also be understood that although one transfer robot 218 is shown in FIG. 1, more than one transfer robot 218 can be accommodated in the transfer chamber 216 and operate in an orchestrated and coordinated manner.

The control system 248 is electrically coupled with the chambers 202a-202d, the load locks 204, the loading robot 232, and the transfer robot 218. The control system 248 is configured to control chambers 202a-202d, the load locks 204, the loading robot 232, and the transfer robot 218.

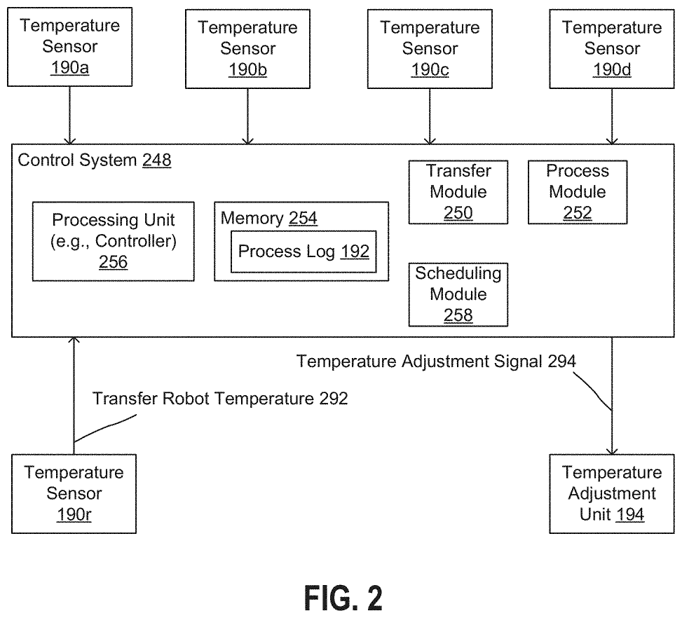

FIG. 2 is a block diagram illustrating an example control system 248 in accordance with some embodiments. In the example shown in FIG. 2, the control system 248 includes, among other things, a processing unit 256, a memory 254, a transfer module 150, a process module 252, and a scheduling module 258. The control system 248 is electrically connected to temperature sensors 190a, 190b, 190c, 190d, and 190r and a temperature adjustment unit 194.

Referring back to FIG. 1, the temperature sensors 190a, 190b, 190c, and 190d are located in the chambers 202a-202d, respectively, and configured to detect the temperatures at the chambers 202a-202d, respectively. The temperature sensor 190r is located at the holding member 224 of the transfer robot 218 and configured to detect the temperature at the holding member 224, which is located in the transfer chamber 216. The temperature adjustment unit 194 is located in proximity to the transfer robot 218. In one embodiment, the temperature adjustment unit 194 is in contact with the transfer robot 218. In one example, the temperature adjustment unit 194 is in contact with the bearing 226 of the transfer robot 218. The temperature adjustment unit 194 can adjust the temperature of the holding member 224 and, therefore, the wafer 102 positioned on the holding member 224.

Referring back to FIG. 2, the control system 248 obtains the transfer robot temperature 292 (i.e., the temperature of the holding member 224) from the temperature sensor 190r in a real-time manner. The control system 248 also obtains the temperatures of the chambers 202a-202d from the temperature sensors 190a, 190b, 190c, and 190d, respectively, in a real-time manner. The control system 248 is configured to generate a temperature adjustment signal 294, and the temperature adjustment unit 194 then adjusts the transfer robot temperature 292 based on the temperature adjustment signal 294. As such, the transfer robot temperature 292 can be dynamically adjusted until the transfer robot temperature 292 obtained from the temperature sensor 190r reaches a target temperature. Therefore, a closed-loop control system is formed.

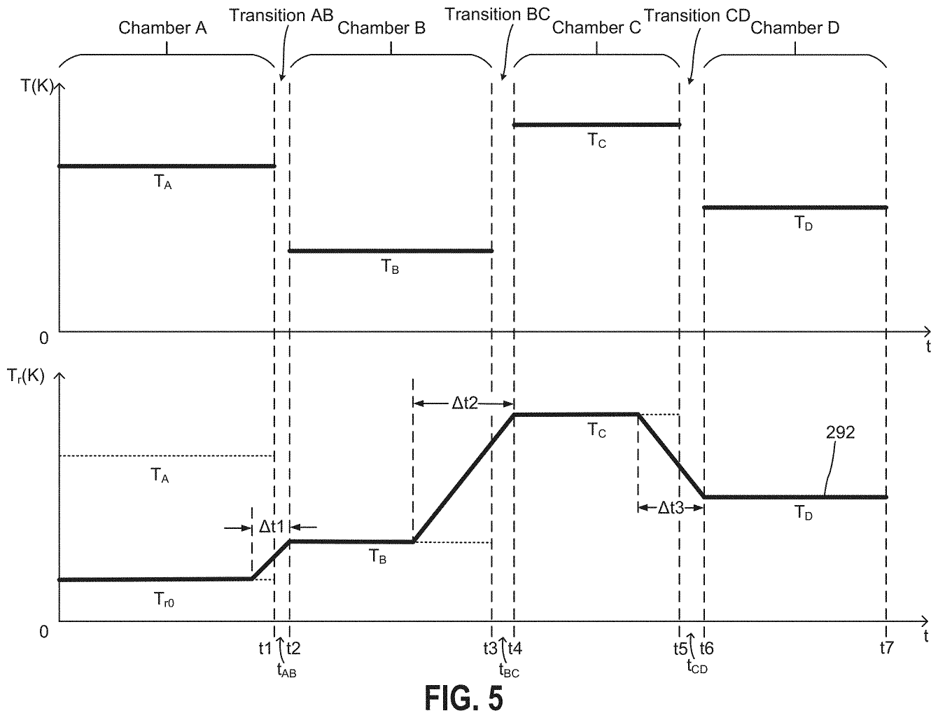

As will be explained in detail below with reference to FIG. 5, the temperature adjustment unit 194 begins to adjust the transfer robot temperature 292 when the wafer 102 is still going through a process in the first chamber 202 (e.g., the chamber 202b), and the target temperature is the target temperature of the second chamber 202 (e.g., the chamber 202d) based on the process log 192. When the wafer 102 exits the first chamber 202, the temperature of the wafer 102 begins to change (i.e., increase or decrease) as the transfer robot temperature 292 changes toward the target temperature of the second chamber due to thermal conduction (because the wafer 102 is placed on and in contact with the transfer robot 218). Therefore, by the time the transfer robot 218 transfers the wafer 102 to the second chamber, the transfer robot temperature 292 and, thus, the temperature of the wafer 102 has reached the target temperature of the second chamber. Accordingly, the delay time due to the temperature difference in different chambers can be significantly reduced or completely avoided, thereby enhancing the productivity of the multi-chamber semiconductor processing system.

The processing unit 256 is configured to execute codes or instructions stored in the memory 254 to cause the control system 248 to perform various functions disclosed herein. In one embodiment, the processing unit 256 is a central processing unit (CPU), a multi-processor, a distributed processing system, an application specific integrated circuit (ASIC), a controller, and/or a suitable processing unit.

The memory 254 is configured to store the codes or instructions that are executed by the processing unit 256. In addition, the memory 254 also stores the process log 192. In various implementations, the memory 254 may include one or more of a solid-state memory, a magnetic tape, a removable computer diskette, a random-access memory (RAM), a read-only memory (ROM), a rigid magnetic disk, an optical disk, and/or a suitable memory device.

The transfer module 250 is configured to control the transfer robot 218 and the loading robot 232 to transfer the wafer 102 among the load locks 204 and the chambers 202a-202d. The process module 252 is configured to control various processes carried out in the chambers 202a-202d. In one implementation, the process module 252 obtains the process log 192 stored in the memory 254 and sends control signals to semiconductor processing equipment corresponding to the chambers 202a-202d to operate them according to the process log 192.

The scheduling module 158 is configured to schedule and coordinate various operations of the multi-chamber semiconductor processing system 100. For instance, the scheduling module 158 can coordinate the timing of the process module 252, the temperature adjustment unit 194, and the transfer module 250. The timing coordination among the process module 252, the temperature adjustment unit 194, and the transfer module 250 will be described in detail below with reference to FIG. 5.

The chambers 202a-202d can be various chambers corresponding to various semiconductor processing equipment. In one example, the chamber 202a is a degassing chamber, the chamber 202b is a physical vapor deposition (PVD) chamber, the chamber 202c is a chemical vapor deposition (CVD), and the chamber 202d is an atomic layer deposition (ALD) chamber. The degassing chamber is used to remove gaseous and/or liquid substances, such as moisture and oxygen, from the wafer 102 to prevent changes in material characteristics, which may cause deposition failure. It should be noted that the example above is not intended to be limiting, and the techniques disclosed herein are generally applicable to multi-chamber semiconductor processing system where different chambers have different target temperatures.

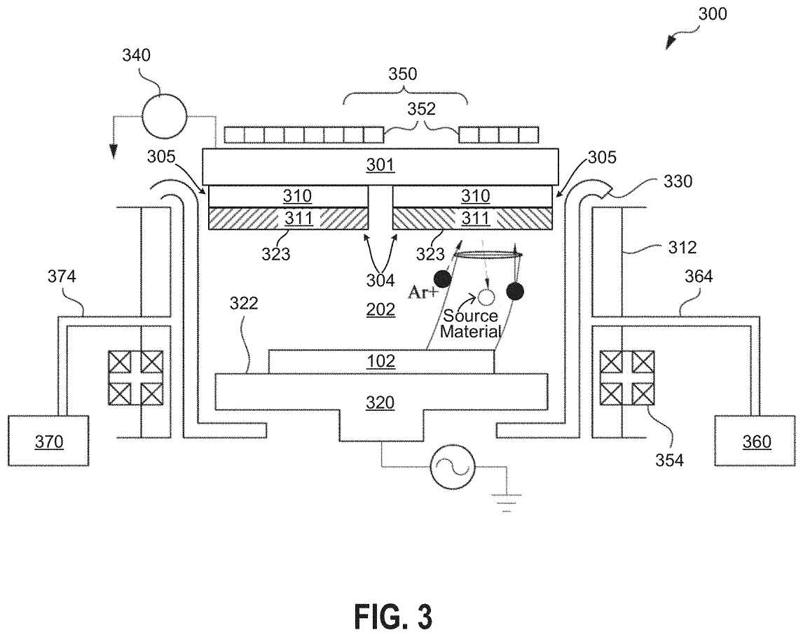

By way of illustration, a PVD chamber is described in greater detail. FIG. 3 is a diagram illustrating is a schematic diagram illustrating an example PVD system 300 in accordance with some embodiments. The PVD system 300 is capable of depositing a film onto a wafer 102 using one or more PVD targets 304. During the PVD process, the one or more PVD targets 304 are bombarded by energetic ions, such as plasma, causing material to be knocked off the one or more PVD targets 304 and deposited as a film on the wafer 102. In the example shown in FIG. 3, there are two PVD targets 304. It should be understood that more than two PVD targets can be used in other examples.

In some embodiments, the PVD system 300 is a magnetron PVD system including a chamber body 312, which encloses a chamber (sometimes also referred to as a “processing region” or a “plasma zone”) 202. A wafer support 320 is disposed within the chamber body 312. The wafer support 320 has a wafer receiving surface 322 that receives and supports the wafer 102 during the PVD process, so that a surface of the wafer 102 is opposite to the front surfaces of 323 the one or more PVD targets 304 that are exposed to the chamber 202. The one or more PVD targets 304 are disposed on a lid 301. The wafer support 320 is electrically conductive and is coupled to ground (GND) so as to define an electrical field between the one or more PVD targets 304 and the wafer 102. In some embodiments, the wafer support 320 is composed of aluminum, stainless steel, or ceramic material. In some embodiments, the wafer support 320 includes an electrostatic chuck that includes a dielectric material.

A shield 330, also referred to as a “dark space shield,” is positioned inside the PVD chamber body 312 and proximate sidewalls 305 of the one or more PVD targets 304 to protect inner surfaces of the chamber body 312 and sidewalls 305 of the one or more PVD targets 304 from unintended deposition. The shield 330 is positioned very close to the target sidewall 305 to minimize re-sputtered material from being deposited thereon. The shield 330 has a plurality of apertures (not shown) defined therethrough for admitting a plasma-forming gas such as argon (Ar) from the exterior of the shield 330 into its interior.

A power supply 340 is electrically coupled to the backing plates 310 of the one or more PVD targets 304 through the lid 301. The backing plates 310 are attached to the target plates 311, which contain different source materials of the PVD targets 304. The power supply 340 is configured to negatively bias the one or more PVD targets 304 with respect to the chamber body 312 to excite a plasma-forming gas, for example, argon (Ar), into a plasma. In some embodiments, the power supply 340 is a direct current (DC) power supply source. In other embodiments, the power supply 340 is a radio frequency (RF) power supply source.

A magnet assembly 350 is disposed above the one or more PVD targets 304. The magnet assembly 350 is configured to project a magnetic field parallel to the front surfaces 323 of the one or more PVD targets 304 to trap electrons, thereby increasing the density of the plasma and increasing the sputtering rate. In some embodiments, the magnet assembly 350 is configured to scan about the back of the one or more PVD targets 304 to improve the uniformity of deposition. In some embodiments, the magnet assembly 350 includes a single magnet disposed above the one or more PVD targets 304. In some embodiments, the magnet assembly 350 includes an array of magnets. In some embodiments and as shown in FIG. 3, the magnet assembly 350 includes a pair of back magnets 352 disposed above the one or more PVD target 304. In some embodiments and as shown in FIG. 3, the magnet assembly 350 also includes a side electromagnet 354 around the chamber body 312.

A gas source 360 is in fluidic combination with the chamber body 312 via a gas supply pipe 364. The gas source 360 is configured to supply a plasma-forming gas to the chamber 202 via the gas supply pipe 364. The plasm-forming gas is an inert gas and does not react with the materials in the one or more PVD targets 304. In some embodiments, the plasma-forming gas includes argon (Ar), xenon (Xe), neon (Ne), or helium (He), which is capable of energetically impinging upon and sputtering source material (and the dopant in some embodiments) from the one or more PVD targets 304. In some embodiments, the gas source 360 is also configured to supply a reactive gas into the PVD system 300. The reactive gas includes one or more of an oxygen-containing gas, a nitrogen-containing gas, a methane-containing gas, that is capable of reacting with the sputtering source material in the one or more PVD targets 304 to form a layer on the wafer 102.

A vacuum device 370 is in fluidic communication with the PVD system 300 via an exhaust pipe 374. The vacuum device 370 is used to create a vacuum environment in the PVD system 300 during the PVD process. In some embodiments, the PVD system 300 has a pressure in a range from about 1 mTorr to about 10 Torr. The spent process gases and byproducts are exhausted from the PVD system 300 through the exhaust pipe 374.

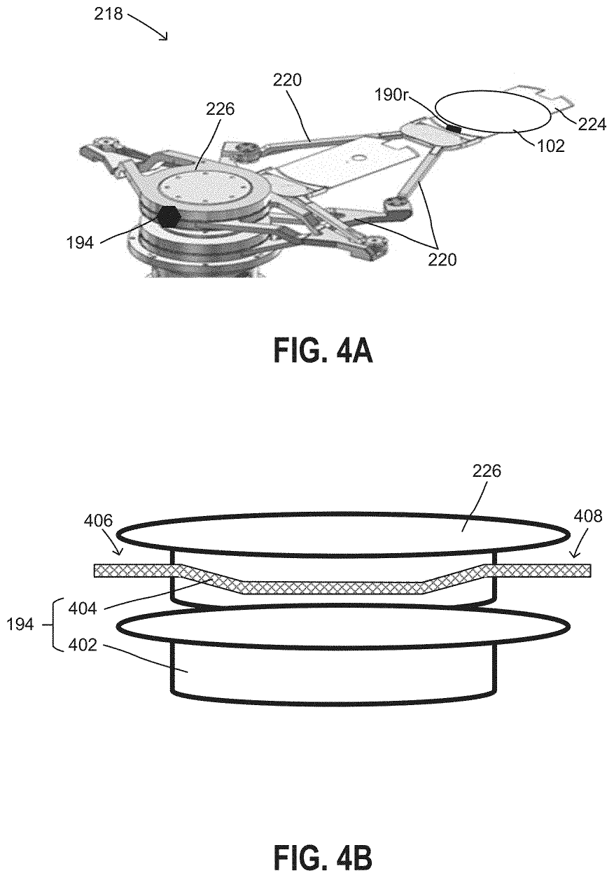

FIG. 4A is a schematic diagram illustrating an example transfer robot 218 in accordance with some embodiments. In the example shown in FIG. 4A, the transfer robot 218 includes, among other things, a bearing 226, a holding member 224, and one or more rods 220 connecting the bearing 226 and the holding member 224, a temperature sensor 190r, and a temperature adjustment unit 194. The holding member 224 is a holding plate in the example shown in FIG. 4A, and a wafer 102 is placed or positioned on it. The temperature sensor 190r is mounted on the holding member 224 and at proximity to the wafer 102. As such, the transfer robot temperature 292 (i.e., the temperature of the holding member 224) can be detected and it is a good approximation of the temperature of the wafer 102 as the temperature sensor 190r is at proximity to the wafer 102.

The temperature adjustment unit 194 is mounted on or attached to the bearing 226. In one embodiment, the temperature adjustment unit 194 includes a heater which can increase the temperature. In another embodiment, the temperature adjustment unit 194 includes a cooling mechanism which can decrease the temperature. In yet another embodiment, the temperature adjustment unit 194 includes both a heater and a cooling mechanism. The temperature adjustment unit 194 increases or decreases the temperature of the bearing 226. Since the bearing 226, the rods 220, and the holding member 224 are all made of metals having good thermal conduction (e.g., aluminum), the transfer robot temperature 292 (i.e., the temperature of the holding member 224) is increased or decreased quickly. As a result, the temperature of the wafer 102 is adjusted accordingly. It should be understood that both the temperature sensor 190r and the temperature adjustment unit 194 are schematic in FIG. 4A.

FIG. 4B is a schematic diagram illustrating an example temperature adjustment unit 194 in accordance with some embodiments. In the example shown in FIG. 4B, the temperature adjustment unit 194 includes a heater 402 and a cooling fluid line 404. The heater 402 is attached to the bearing 226 and can increase the temperature of the bearing 226 through thermal conduction. The cooling fluid line 404 forms a route along which the cooling fluid flows. The cooling fluid line 404 winds the bearing 226 and has an inlet 406 and an outlet 408. When the cooling fluid flows in the cooling fluid line 404, the temperature of the bearing is decreased through thermal conduction. In one implementation, the cooling fluid is cooling water. In another implementation, the cooling fluid is liquid nitride. It should be understood that these examples are not intended to be limiting, and other cooling mechanisms or other types of cooling fluid may be employed in other embodiments.

FIG. 5 is a timing diagram illustrating the operation of the multi-chamber semiconductor processing system in accordance with some embodiments. The upper half of FIG. 5 illustrates the target temperatures (T) of four chambers, whereas the lower half of FIG. 5 illustrates the transfer robot temperature 292 (Tr). It should be understood that FIG. 5 is illustrative and not drawn to scale.

In the example shown in FIG. 5, the transfer robot 218 transfers the wafer 102 to chamber A, chamber B, chamber C, and chamber D in order according to the process log 192. The wafer 102 is in chamber A between the start (i.e., t=0, as shown in FIG. 5) and the moment t1. After a transition period “AB” (i.e., t_{AB}=t2−t1, as shown in FIG. 5), the wafer 102 is in chamber B between the moment t2 and the moment t3. After another transition period “BC” (i.e., t_{BC}=t4−t3, as shown in FIG. 5), the wafer 102 is in chamber C between the moment t4 and the moment t5. After yet another transition period “CD” (i.e., t_{CD}=t6−t5, as shown in FIG. 5), the wafer 102 is in chamber D between the moment t6 and the moment t7. In this example shown in FIG. 5, the process flow ends after the wafer 102 is being processed in chamber D. It should be understood that this is exemplary rather than limiting, and there could be more processes than those shown in FIG. 5.

Chamber A has a target temperature T_{A}; chamber B has a target temperature T_{B}; chamber B has a target temperature T_{C}; and chamber B has a target temperature T_{D}. On the other hand, the transfer robot temperature 292 has an initial temperature Tᵣ₀, which is typically the environment temperature of the transfer chamber 216 shown in FIG. 1 at the beginning. Likewise, these temperatures are illustrative rather than limiting.

As explained above, the temperature of the wafer 102 begins to adjust after it has been transferred to a new chamber, in a conventional multi-chamber semiconductor processing system. As a result, there is some delay time due to the temperature difference in different chambers. The delay time that exists every time the wafer is transferred to a new chamber can collectively result in a loss in productivity.

In contrast, and as explained above, the temperature adjustment unit 194 shown in FIG. 2 begins to adjust the transfer robot temperature 292 when the wafer 102 is still going through a process in the current chamber (e.g., chamber A), and the target temperature is the target temperature of the next chamber (e.g., chamber B) based on the process log 192. When the wafer 102 exits the current chamber, the temperature of the wafer 102 begins to change (i.e., increase or decrease) as the transfer robot temperature 292 changes toward the target temperature of the next chamber due to thermal conduction. Therefore, by the time the transfer robot 218 transfers the wafer 102 to the next chamber, the transfer robot temperature 292 and, therefore, the temperature of the wafer 102 has reached the target temperature of the next chamber.

In one implementation, the temperature adjustment unit 194 adjusts the transfer robot temperature 292 according to the temperature adjustment signal 294 shown in FIG. 2, and the temperature adjustment signal 294 is generated based on the target temperature of the next chamber and the current value of the transfer robot temperature 292.

For instance, the transfer robot temperature 292 begins to change prior to the moment t1, and the adjustment period Δt1 can be determined based on the difference in temperature (i.e., T_{B}−Tᵣ₀) and the characteristics of the transfer robot 218 (such as thermal conductivity of the material). As such, some time (i.e., Δt1−t_{AB}) is saved using the techniques disclosed herein because the transition period “AB” (i.e., t_{AB}=t2−t1, as shown in FIG. 5) is needed anyway for transferring the wafer 102. In one embodiment, the transfer robot temperature 292 is maintained at T_{B} after the moment t2.

Likewise, the transfer robot temperature 292 begins to change prior to the moment t3, and the adjustment period Δt2 can be determined based on the difference in temperature (i.e., T_{C}−T_{B}) and the characteristics of the transfer robot 218 (such as thermal conductivity of the material). As such, some time (i.e., Δt2−t_{BC}) is saved using the techniques disclosed herein because the transition period “BC” (i.e., t_{AB}=t4−t3, as shown in FIG. 5) is needed anyway for transferring the wafer 102. In one embodiment, the transfer robot temperature 292 is maintained at T_{C} after the moment t4.

Likewise, the transfer robot temperature 292 begins to change prior to the moment t5, and the adjustment period Δt3 can be determined based on the difference in temperature (i.e., T_{C}−T_{D}) and the characteristics of the transfer robot 218 (such as thermal conductivity of the material). As such, some time (i.e., Δt3−t_{CD}) is saved using the techniques disclosed herein because the transition period “CD” (i.e., t_{CD}=t6−t5, as shown in FIG. 5) is needed anyway for transferring the wafer 102. In one embodiment, the transfer robot temperature 292 is maintained at T_{D} after the moment t6.

Thus, the total time saved (i.e., total reduction in time) can be determined by adding the time saved (i.e., reduction in time) every time the wafer 102 is transferred from one chamber to another chamber having a different target temperature. In the example shown in FIG. 5, the total reduction in time can be determined by the equation below.

Total Reduction in Time=Δt1+Δt2+Δt3−t_{AB}−t_{BC}−t_{CD}.

Accordingly, the delay time due to the temperature difference in different chambers can be significantly reduced or completely avoided, thereby enhancing the productivity of the multi-chamber semiconductor processing system.

It should be understood that, in another embodiment, the transfer robot temperature 292 has an initial temperature Tᵣ₀, which is the target temperature of chamber A (i.e., T_{A} shown in FIG. 5). The principles explained above are still applicable.

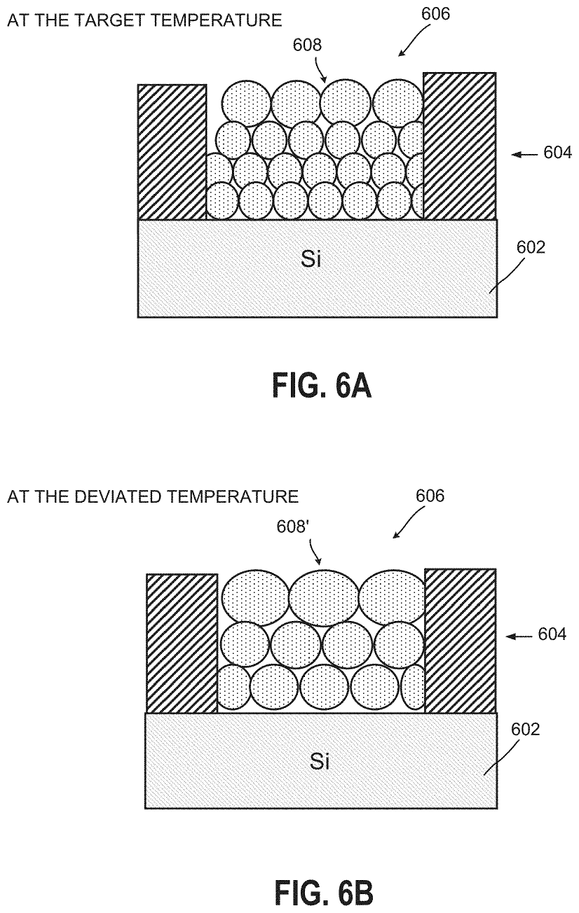

FIG. 6A is a diagram illustrating an example film formed under the target temperature in accordance with some embodiments. FIG. 6B is a diagram illustrating an example film formed under a deviated temperature in accordance with some embodiments. As shown in FIGS. 6A and 6B, a film 608 and 608′ are respectively deposited in a trench 606 opened in a semiconductor layer 604, which is formed on the silicon substrate 602.

The film 608 is deposited using the multi-chamber semiconductor system 100 shown in FIG. 1, and the temperature is at the target temperature of the chamber 202 shown in FIG. 1. In contrast, the film 608′ is deposited using a conventional multi-chamber semiconductor system, and the temperature is at a deviated temperature (e.g., 20 Kelvin higher than the target temperature) of the chamber because the process is carried out prematurely (i.e., before the temperature of the wafer drops to the target temperature). As a result, the film 608 has a grain size of 0.96 μm, while the film 608′ has a grain size of 1.2 μm. That is, the temperature deviation results in a 25% deviation in grain size. Therefore, the multi-chamber semiconductor system 100 shown in FIG. 1 and the techniques disclosed herein can help avoid such unwanted film property degradation.

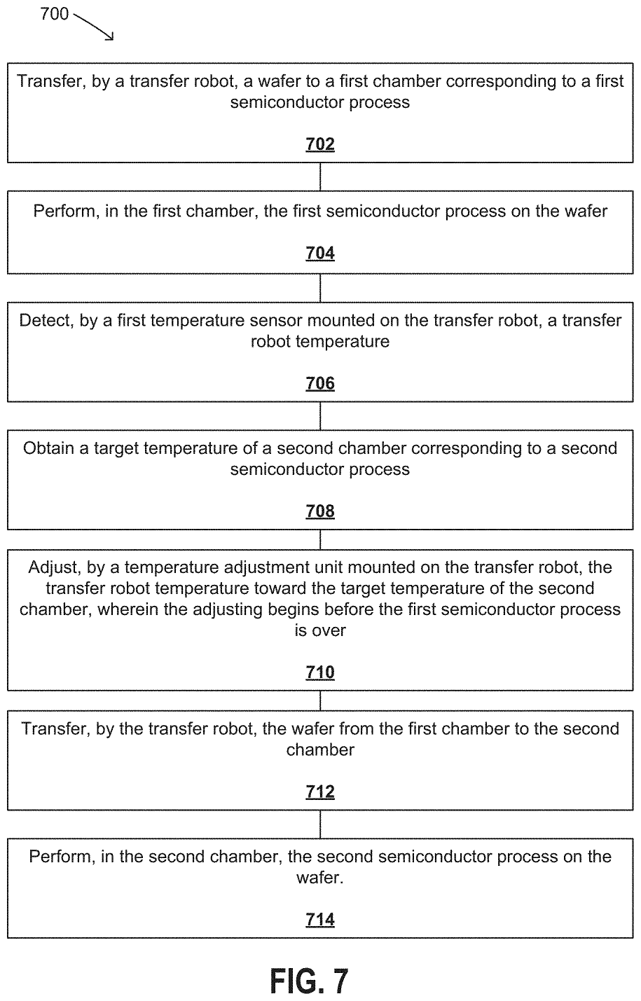

FIG. 7 is a flowchart diagram illustrating an example method 700 in accordance with some embodiments. In the example shown in FIG. 7, the method 700 includes operations 702, 704, 706, 708, 710, 712, and 714. Additional operations may be performed. Also, it should be understood that the sequence of the various operations discussed above with reference to FIG. 7 is provided for illustrative purposes, and as such, other embodiments may utilize different sequences. These various sequences of operations are to be included within the scope of embodiments.

At operation 702, a transfer robot (e.g., the transfer robot 218 shown in FIG. 1) transfers a wafer (e.g., the wafer 102 shown in FIG. 4A) to a first chamber (e.g., the chamber 202a shown in FIG. 1) corresponding to a first semiconductor process. At operation 704, the first semiconductor process is performed on the wafer in the first chamber.

At operation 706, a first temperature sensor (e.g., the temperature sensor 190r shown in FIG. 1) mounted on the transfer robot detects a transfer robot temperature (e.g., the transfer robot temperature 292 shown in FIG. 2). At operation 708, a target temperature of a second chamber corresponding to a second semiconductor process is obtained. In one implementation, the target temperature of the second chamber is obtained based on the process log (e.g., the process log 192 shown in FIG. 2).

At operation 710, a temperature adjustment unit (e.g., the temperature adjustment unit 194 shown in FIG. 4B) mounted on the transfer robot adjusts the transfer robot temperature toward the target temperature of the second chamber. The adjusting begins before the first semiconductor process is over.

At operation 712, the transfer robot transfers the wafer from the first chamber to the second chamber. At operation 714, the second semiconductor process is performed on the wafer in the second chamber.

In accordance with some aspects of the disclosure, a multi-chamber semiconductor processing system is provided. The multi-chamber semiconductor processing system includes: a plurality of chambers, each of the plurality of chambers corresponding to a semiconductor process; a transfer chamber; a transfer robot in the transfer chamber and having a holding member capable of holding a wafer, the transfer robot configured to transfer the wafer among the plurality of chambers; a first temperature sensor mounted on the holding member and configured to detect a transfer robot temperature; and a temperature adjustment unit mounted on the transfer robot and configured to adjust the transfer robot temperature.

In accordance with some aspects of the disclosure, a method for operating a multi-chamber semiconductor processing system is provided. The method includes the following steps: transferring, by a transfer robot, a wafer to a first chamber corresponding to a first semiconductor process; performing, in the first chamber, the first semiconductor process on the wafer; detecting, by a first temperature sensor mounted on the transfer robot, a transfer robot temperature; obtaining a target temperature of a second chamber corresponding to a second semiconductor process; adjusting, by a temperature adjustment unit mounted on the transfer robot, the transfer robot temperature toward the target temperature of the second chamber, wherein the adjusting begins before the first semiconductor process is over; transferring, by the transfer robot, the wafer from the first chamber to the second chamber; and performing, in the second chamber, the second semiconductor process on the wafer.

In accordance with some aspects of the disclosure, a multi-chamber semiconductor processing system is provided. The multi-chamber semiconductor processing system includes: a first chamber corresponding to a first semiconductor process; a second chamber corresponding to a second semiconductor process; a transfer chamber; a transfer robot in the transfer chamber and having a holding member capable of holding a wafer, the transfer robot configured to transfer the wafer between the first chamber and the second chamber; a first temperature sensor mounted on the holding member and configured to detect a temperature of the holding member; a control system configured to generate a temperature adjustment signal based on a target temperature of the second chamber; and a temperature adjustment unit mounted on the transfer robot and configured to adjust the temperature of the holding member according to the temperature adjustment signal, wherein the temperature adjustment unit begins to adjust the temperature of the holding member before the first semiconductor process is over.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A multi-chamber semiconductor processing system comprising:
a plurality of chambers, each of the plurality of chambers corresponding to a semiconductor process;
a transfer chamber;
a transfer robot in the transfer chamber and having a holding member capable of holding a wafer, the transfer robot configured to transfer the wafer among the plurality of chambers;
a first temperature sensor mounted on the holding member and configured to detect a transfer robot temperature; and
a temperature adjustment unit mounted on the transfer robot and configured to adjust the transfer robot temperature.

2. The multi-chamber semiconductor processing system of claim 1, wherein the transfer robot temperature is a temperature of the holding member.

3. The multi-chamber semiconductor processing system of claim 1, further comprising:
a control system configured to generate a temperature adjustment signal, and wherein the temperature adjustment unit adjusts the transfer robot temperature according to the temperature adjustment signal.

4. The multi-chamber semiconductor processing system of claim 3, wherein the control system comprising:
a memory, wherein a process log is stored in the memory; and
a processing unit configured to generate the temperature adjustment signal based at least on the process log and the transfer robot temperature.

5. The multi-chamber semiconductor processing system of claim 4, further comprising:
a plurality of temperature sensors located in the plurality of chambers, respectively, and electrically connected to the control system.

6. The multi-chamber semiconductor processing system of claim 4, the process log comprises a plurality of target temperatures corresponding to the plurality of chambers, respectively.

7. The multi-chamber semiconductor processing system of claim 6, the temperature adjustment unit begins to adjust the transfer robot temperature when the wafer is still in a first chamber.

8. The multi-chamber semiconductor processing system of claim 7, the temperature adjustment unit adjusts the transfer robot temperature toward the target temperature of a second chamber, the second chamber being the next chamber according to the process log.

9. The multi-chamber semiconductor processing system of claim 1, wherein the temperature adjustment unit comprises:
a heater configured to increase the transfer robot temperature; and
a cooling mechanism configured to decrease the transfer robot temperature.

10. The multi-chamber semiconductor processing system of claim 9, wherein the cooling mechanism comprises a cooling fluid line.

11. The multi-chamber semiconductor processing system of claim 10, wherein the transfer robot comprises:
a bearing, wherein the heater is attached to the bearing, and the cooling fluid line winds the bearing; and
one or more rods connecting the bearing and the holding member.

12. The multi-chamber semiconductor processing system of claim 11, wherein the bearing, the one or more rods, and the holding member comprises aluminum.

13. The multi-chamber semiconductor processing system of claim 1, further comprising:
a main frame, wherein the transfer chamber is located in the main frame, and the plurality of chambers are laterally spaced around and abutting the main frame.

14. A method for operating a multi-chamber semiconductor processing system, comprising:
transferring, by a transfer robot, a wafer to a first chamber corresponding to a first semiconductor process;
performing, in the first chamber, the first semiconductor process on the wafer;
detecting, by a first temperature sensor mounted on the transfer robot, a transfer robot temperature;
obtaining a target temperature of a second chamber corresponding to a second semiconductor process;
adjusting, by a temperature adjustment unit mounted on the transfer robot, the transfer robot temperature toward the target temperature of the second chamber, wherein the adjusting begins before the first semiconductor process is over;
transferring, by the transfer robot, the wafer from the first chamber to the second chamber; and
performing, in the second chamber, the second semiconductor process on the wafer.

15. The method of claim 14, wherein the transfer robot temperature is a temperature of the transfer robot.

16. The method of claim 14, further comprising:
generating, by a control system, a temperature adjustment signal, and wherein the temperature adjustment unit adjusts the transfer robot temperature according to the temperature adjustment signal.

17. The method of claim 16, wherein the temperature adjustment signal is generated based on the target temperature of a second chamber and a current value of the transfer robot temperature.

18. A multi-chamber semiconductor processing system comprising:
a first chamber corresponding to a first semiconductor process;
a second chamber corresponding to a second semiconductor process;
a transfer chamber;
a transfer robot in the transfer chamber and having a holding member capable of holding a wafer, the transfer robot configured to transfer the wafer between the first chamber and the second chamber;
a first temperature sensor mounted on the holding member and configured to detect a temperature of the holding member;
a control system configured to generate a temperature adjustment signal based on a target temperature of the second chamber; and
a temperature adjustment unit mounted on the transfer robot and configured to adjust the temperature of the holding member according to the temperature adjustment signal, wherein the temperature adjustment unit begins to adjust the temperature of the holding member before the first semiconductor process is over.

19. The multi-chamber semiconductor processing system of claim 18, wherein the temperature adjustment unit comprises:
a heater configured to increase the temperature of the holding member; and
a cooling mechanism configured to decrease the temperature of the holding member.

20. The multi-chamber semiconductor processing system of claim 19, wherein the transfer robot comprises:
a bearing, wherein the heater is attached to the bearing, and the cooling mechanism is a cooling fluid line winding the bearing; and
one or more rods connecting the bearing and the holding member.
